(19) United States
(12) Patent Application Publication
(10) Pub. No.: US 2011/0253672 A1
(43) Pub. Date: Oct. 20, 2011

(54) PLASMA PROCESSING APPARATUS AND PLASMA PROCESSING METHOD

(75) Inventors: Masami Kamibayashi, Kokubunji (JP); Masahito Mori, Kudamatsu (JP); Hiroyuki Kobayashi, Kodaira (JP); Keizo Suzuki, Kodaira (JP); Naoyuki Kofuji, Tama (JP)

(73) Assignee: Hitachi High-Technologies Corporation

(21) Appl. No.: 12/855,206

(22) Filed: Aug. 12, 2010

(30) Foreign Application Priority Data
Apr. 19, 2010 (JP) 2010-096122

(51) Int. Cl. C23F 1/12; H01L 21/306; C23F 1/08

(52) U.S. Cl. 216/61; 156/345.29; 156/345.24; 216/67

(57) ABSTRACT

The present invention is intended to improve the uniformity in a distribution function of incident ion energy inside a wafer surface, and realize uniform plasma processing (etching or the like) inside the wafer surface. In a plasma processing apparatus, a bias application portion of a placement electrode on which a wafer is placed is divided into an inner electrode and an outer electrode at positions near the center of the wafer and the edge thereof. Each of a first bias power and a second bias power to be used to accelerate ions incident on the wafer is bifurcated, and the resultant bias powers are fed to the inner electrode and outer electrode using a power distributor by adjusting the power ratio.

### CLAIM OF PRIORITY

The present application claims priority from Japanese patent application JP 2010-096122 filed on Apr. 19, 2010, the content of which is hereby incorporated by reference into this application.

### BACKGROUND OF THE INVENTION

1. Field of the Invention

The present invention relates to a plasma processing apparatus for use in fabrication of electronic components such as a semiconductor device, and a plasma processing method to be implemented in the apparatus.

2. Description of the Related Art

High-density integration, high-speed operation, and high functionality of a metal oxide semiconductor field-effect transistor (MOSFET) device employed in information communication equipment, power controller, or the like have been accomplished mainly through miniaturization of a polysilicon/silicon dioxide (SiO₂)-structure gate electrode. Introduction of a novel material and a novel structure has been discussed as an approach to further improvement of performance.

In dry etching processing to be used as a method of forming a gate electrode of a MOSFET on a silicon wafer, a reactive gas is recomposed into plasma, and a gate electrode material is etched through ion assisted reaction caused by ions, which are generated in the plasma, and neutral radicals.

A plasma processing apparatus that embodies the above method includes a processing chamber in which a silicon wafer is processed in plasma, a high-frequency power supply that produces the plasma, a processing gas feeding mechanism that feeds a processing gas to the processing chamber, a vacuum exhaust system for decreasing or adjusting the pressure in the processing chamber, a placement electrode (sample stage) on which the wafer is placed, and a high-frequency bias power supply for use in accelerating ions incident on the wafer.

When the plasma processing apparatus having the foregoing constitution is employed, an ion energy distribution function (IEDF) for ions incident on the silicon wafer can be controlled based on a bias application method. For example, when a high-frequency bias is applied, the waveform or frequency of the high-frequency bias is known to affect the IEDF. A proposal has been made that silicon etching selectivity in etching an insulating film can be improved by adopting a method of applying a pulsating bias and biases of two frequencies of a low frequency of 5 kHz or less and a high frequency of 2 MHz or more (refer to, for example, Japanese Patent Application Laid-Open Publication No. 2002-141341). The frequency of the high-frequency bias has been reported to relate to an IEDF that depends on a time it takes plasma to pass through a sheath (refer to for example, “Journal of Vacuum Science and Technology A” (Vol. 20, p. 1759).

### SUMMARY OF THE INVENTION

In order to make a processed shape inside a wafer (an entity to be processed) surface uniform, an ion flux incident on the wafer and an energy distribution function thereof are preferably uniform inside the wafer surface. However, since impedance occurring from an electrode surface to a grounded internal wall of a processing chamber varies depending on a frequency, if a power ratio of a first wafer bias power to a second wafer bias power is changed in a plasma processing apparatus including a first wafer bias power supply and a second wafer bias power supply, a whole wafer surface distribution of a bias power applied to the wafer, that is, an energy distribution function of ions incident on the wafer varies. Therefore, when the ratio of one of two wafer bias powers of different frequencies to the other thereof is changed, an inner-surface distribution of incident-ion energy may vary. A unit that corrects the distribution to make it uniform is preferably included.

An object of the present invention is to provide a plasma processing apparatus and a plasma processing method for upgrading the uniformity in a distribution function of incident ion energy inside the surface of an entity to be processed (wafer or the like), and realizing plasma processing (etching or the like) that is uniform inside a wafer surface.

As an embodiment for accomplishing the above object, there is provided a plasma processing apparatus comprising a processing chamber, a processing gas feeding system that feeds processing gases to the processing chamber, a high-frequency power supply for use in producing plasma from the processing gases, a placement electrode which is disposed in the processing chamber and on which an entity to be processed is placed, and a first bias power supply and a second bias power supply that are used to accelerate ions which are present in the plasma and incident on the entity to be processed and that handle mutually different frequencies. Herein, the placement electrode has a bias application portion thereof electrically divided into two electrodes of an inner electrode and an outer electrode at positions near the center of the entity to be processed and the periphery thereof. Further, the plasma processing apparatus comprises a power distributor for the first high-frequency bias power supply capable of bifurcating a bias power outputted from the first bias power supply, and feeding the resultant bias powers to the inner electrode and outer electrode while adjusting the power ratio, and a power distributor for the second high-frequency bias power supply capable of bifurcating a bias power outputted from the second bias power supply, and feeding the resultant bias powers to the inner electrode and outer electrode while adjusting the power ratio.

A plasma processing method employing the foregoing plasma processing apparatus includes a step of generating plasma, and a step of bringing an ion energy distribution function to a distribution, which is uniform inside the surface of the entity to be processed, by adjusting the bias powers outputted from the first bias power supply and second bias power supply.

Further, a plasma processing apparatus comprises a processing chamber, a processing gas feeding system that feeds a processing gas to the processing chamber, a high-frequency power supply for use in producing plasma from the processing gas, a placement electrode which is disposed in the processing chamber and on which an entity to be processed is placed, and a first bias power supply and a second bias power supply that are used to accelerate ions which are present in the plasma and incident on the entity to be processed and that handle mutually different frequencies. Further, the plasma processing apparatus comprises an inner ground electrode and an outer ground electrode that are disposed in an upper part of the processing chamber and opposed to the placement electrode, a first impedance matcher connected to the inner ground electrode, and a second impedance matcher connected to the outer ground electrode.

Further, a plasma processing method employing the foregoing plasma processing apparatus comprises a step of generating plasma, and a step of bringing an ion energy distribution function to a distribution, which is uniform inside the surface of the entity to be processed, by adjusting the first impedance matcher and second impedance matcher.

Owing to the foregoing constitution, a plasma processing apparatus and a plasma processing method for upgrading the uniformity in a distribution function of incident ion energy inside the surface of an entity to be processed (wafer), and realizing plasma processing (etching or the like) that is uniform inside the wafer surface.

### BRIEF DESCRIPTION OF THE DRAWINGS

FIG. 1 is a schematic sectional view of a plasma processing apparatus in accordance with a first embodiment;

FIG. 2 is a diagram for explaining applications of powers from bias power supplies connected to an entity-to-be-treated placement electrode;

FIG. 3A is a diagram showing ion energy distribution function observed in the center part of an entity to be processed and the perimetric part thereof;

FIG. 3B is a diagram showing ion energy distribution function observed in the center part of the entity to be processed and the perimetric part thereof;

FIG. 3C is a diagram showing ion energy distribution function observed in the center part of the entity to be processed and the perimetric part thereof;

FIG. 3D is a diagram showing ion energy distribution function observed in the center part of the entity to be processed and the perimetric part thereof;

FIG. 4A is a diagram for explaining a condition for bias power application associated with the ion energy distribution function of FIG. 3A;

FIG. 4B is a diagram for explaining a condition for bias power application associated with the ion energy distribution function of FIG. 3B;

FIG. 4C is a diagram for explaining a condition for bias power application associated with the ion energy distribution function of FIG. 3C;

FIG. 4D is a diagram for explaining a condition for bias power application associated with the ion energy distribution function of FIG. 3D;

FIG. 5 is a diagram for explaining control of the uniformity in an IEDF inside the surface of the entity to be processed;

FIG. 6 is a diagram presenting a procedure of controlling the uniformity in an IEDF;

FIG. 7 is a diagram presenting a procedure of controlling the uniformity in a processed shape;

FIG. 8 is a diagram for explaining applications of powers from bias power supplies connected to an entity-to-be-treated placement electrode of a plasma processing apparatus in accordance with a second embodiment;

FIG. 9 is a diagram for explaining applications of powers from bias power supplies connected to an entity-to-be-treated placement electrode of a plasma processing apparatus in accordance with a third embodiment;

FIG. 10 is a diagram for explaining applications of powers from bias power supplies connected to an entity-to-be-treated placement electrode of a plasma processing apparatus in accordance with a fourth embodiment;

FIG. 11 is a schematic diagram of a plane (upper part) of an entity-to-be-treated placement electrode of the plasma processing apparatus in accordance with the first embodiment, and a section (lower part) thereof; and

FIG. 12 is a diagram for explaining applications of powers from bias power supplies connected to an entity-to-be-treated placement electrode of a plasma processing apparatus in accordance with a fifth embodiment.

### DESCRIPTION OF THE PREFERRED EMBODIMENTS

### First Embodiment

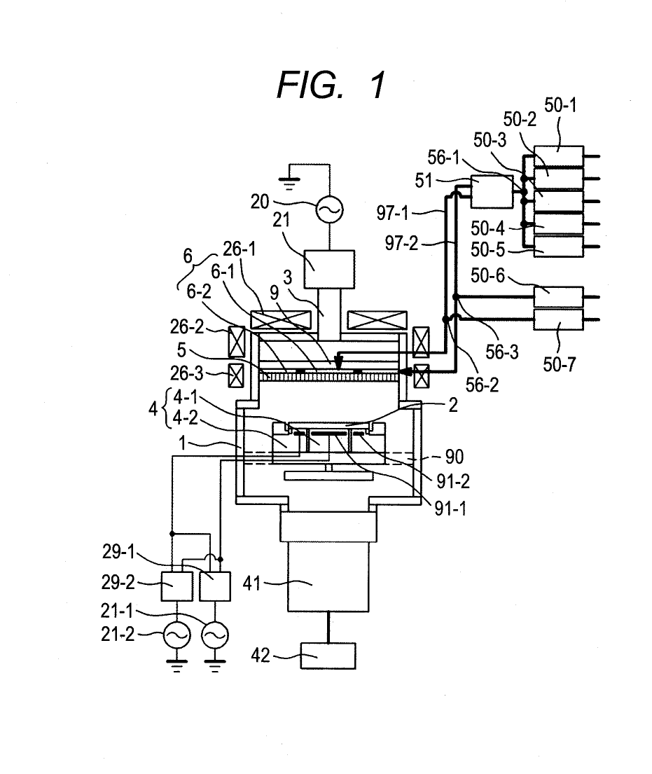

A first embodiment of the present invention will be described below in conjunction with FIG. 1 to FIG. 7. FIG. 1 is a schematic sectional view of a plasma processing apparatus (plasma etching apparatus or the like) in accordance with the present embodiment. A waveguide 3 for introducing a high-frequency power, which is used to produce plasma, from above is disposed in a processing chamber (etching chamber or the like) 1. A high-frequency power supply 20 for use in producing the plasma is connected to the waveguide via a matcher 21.

An upper coil 26-1, a middle coil 26-2, and a lower coil 26-3 for producing a magnetic field are disposed outside the processing chamber 1, and the efficiency in plasma production is enhanced through electron cyclotron resonance. A productive distribution of plasma or a transportational distribution thereof can be controlled by changing a magnetic-field distribution in the processing chamber. Namely, a spatial electron density distribution in the processing chamber can be controlled. Therefore, the whole wafer surface uniformity in an ion flux incident on the entity to be processed (silicon wafer or the like) can be controlled.

A quartz-made top plate 9 is disposed below the waveguide 3, and a quartz-made shower plate 5 for use in feeding a gas into the processing chamber 1 is disposed immediately below the top plate 9. The shower plate 5 has plural microscopic gas holes, and a processing gas is fed to the processing chamber 1 through the gas holes.

In order to control a compositional distribution of a processing gas in the processing chamber 1 or a flowing distribution thereof, a gas dispersion area 6 formed between the shower plate 5 and top plate 9 is divided into an inner area 6-1 and an outer area 6-2, so that the flow rates of a processing gas to be fed through an inner area of the shower plate 5 and a processing gas to be fed through an outer area of the shower plate 5, or the compositional ratios of the gases can be controlled mutually independently.

A processing gas feeding system adjusts the flow rates of gases, which are fed from plural gas feeding sources (not shown), through mass-flow controllers 50-1 and 50-7. The gases fed through the mass-flow controllers 50-1 to 50-5 are joined at a gas junction 56-1 downstream the mass-flow controllers, whereby a first gas is produced. On a downstream side of the gas junction 56-1, the first gas is bifurcated at a predetermined flow-rate ratio by a gas distributor 51. The resultant gases are fed to a first gas feeding line 97-1 and a second gas feeding line 97-2.

Further, a second gas fed through the mass-flow controllers 50-6 and 50-7 is added to the first gas, which is bifurcated into two parts, at gas junctions 56-2 and 56-3 in order to produce a first processing gas and a second processing gas. The first processing gas is fed to the inner area of the shower plate 5, and the second processing gas is fed to the outer area of the shower plate. Thus, the controllability of a radical distribution in the processing chamber 1 is improved. Herein, the gases to be fed through the mass-flow controllers 50-1 to 50-5 are, for example, argon (Ar), chlorine (Cl₂), hydrogen bromide (HBr), hydrogen chloride (HCl), and sulfur hexafluoride (SF₆). A gas to be fed through the mass-flow controllers 50-6 and 50-7 is oxygen (O₂) or the like.

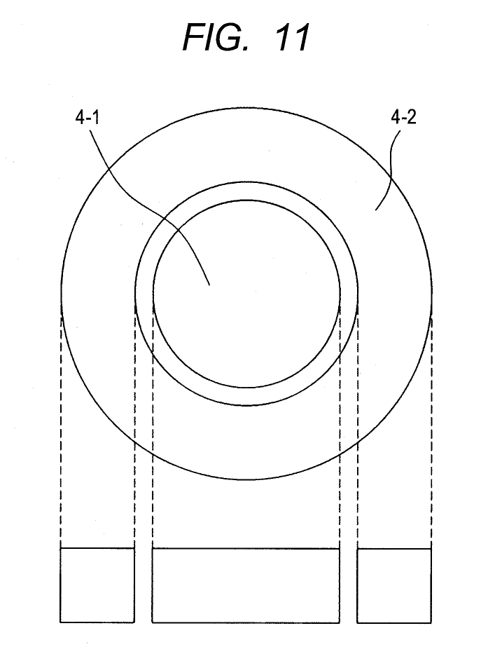

In the processing chamber 1, an entity-to-be-treated placement electrode (sample stage) 4 on which an entity to be processed (silicon wafer or the like) 2 is placed is disposed to be opposed to the shower plate 5. The placement electrode 4 includes an inner electrode 4-1 and an outer electrode 4-2 that are electrically separated from each other. The planar shape of the inner electrode (sample stage) 4-1 is round, and the planar shape of the outer electrode (sample stage) 4-2 is annular (FIG. 11). In order to accelerate ions incident on the entity to be processed 2, a first high-frequency bias power supply 21-1 and a second high-frequency bias power supply 21-2 are connected to the placement electrode (sample stage) 4.

The frequency of a high-frequency power to be outputted from the first high-frequency bias power supply 21-1 is 400 kHz, while the frequency of a high-frequency power to be outputted from the second high-frequency bias power supply 21-2 is 4 MHz. The high-frequency powers outputted from the two high-frequency power supplies are bifurcated by a power distributor 29-1 for the first high-frequency bias power supply and a power distributor 29-2 for the second high-frequency bias power supply. The high-frequency powers distributed by the power distributors are applied to the inner electrode 4-1 and outer electrode 4-2. Incidentally, reference numeral 41 denotes a turbo molecular pump, and reference numeral 42 denotes a dry pump. Reference numeral 90 denotes a support member for the entity-to-be-treated placement electrode (sample stage) on which the entity to be processed (silicon wafer or the like) 2 is placed. Reference numeral 91-1 denotes an inner electrode plate, and reference numeral 91-2 denotes an outer electrode plate.

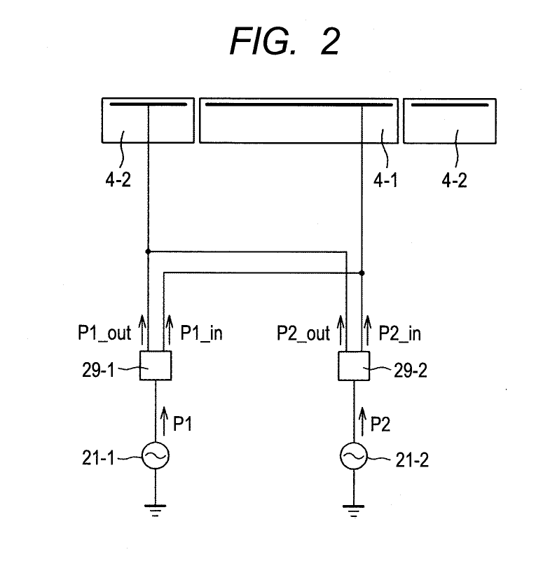

Referring to FIG. 2, definitions of a power and a power ratio will be described below. FIG. 2 is a diagram for explaining applications of powers from two wafer bias power supplies connected to the wafer placement electrode (sample stage) 4. Assume that P1 denotes a first high-frequency bias power to be outputted from the first high-frequency bias power supply 21-1, and P2 denotes a second high-frequency bias power to be outputted from the second high-frequency bias power supply 21-2.

Assume that P1_in denotes a first high-frequency bias power to be applied to the inner electrode (sample stage) 4-1, P1_out denotes the first high-frequency bias power to be applied to the outer electrode (sample stage) 4-2, and P1_in:P1_out denotes an inner-to-outer power ratio of the first bias power. Assume that P2_in denotes a second high-frequency bias power to be applied to the inner electrode (sample stage) 4-1, P2_out denotes the second high-frequency bias power to be applied to the outer electrode 4-2, and P2_in:P2_out denotes an inner-to-outer power ratio of the second bias power.

The power distributor 29-1 for the first high-frequency bias power supply and the power distributor 29-2 for the second high-frequency bias power supply are provided with an impedance control capability and a high-frequency filter capability, and can therefore mutually independently control the inner-to-outer power ratio of the first bias power and the inner-to-outer power ratio of the second bias power. The wafer placement electrode (sample stage) is structured to have plates (an inner electrode plate 91-1 and an outer electrode plate 91-2), to which a bias is applied, embedded in a sprayed film thereof containing, for example, titanium nitride (TiN) or yttrium oxide (Y₂O₃), as a major component thereof, and is devised so that the two plates can be isolated from each other on a high-frequency basis to the greatest possible extent.

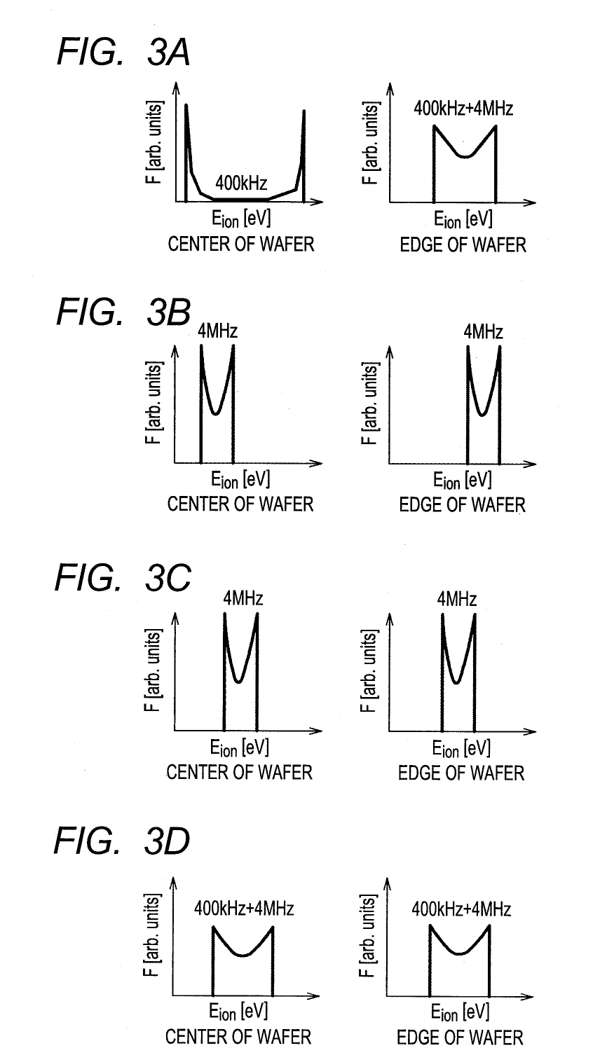

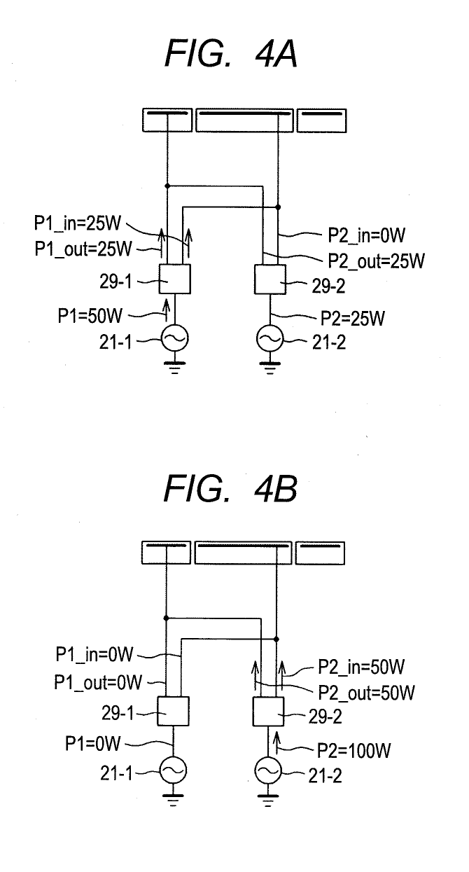

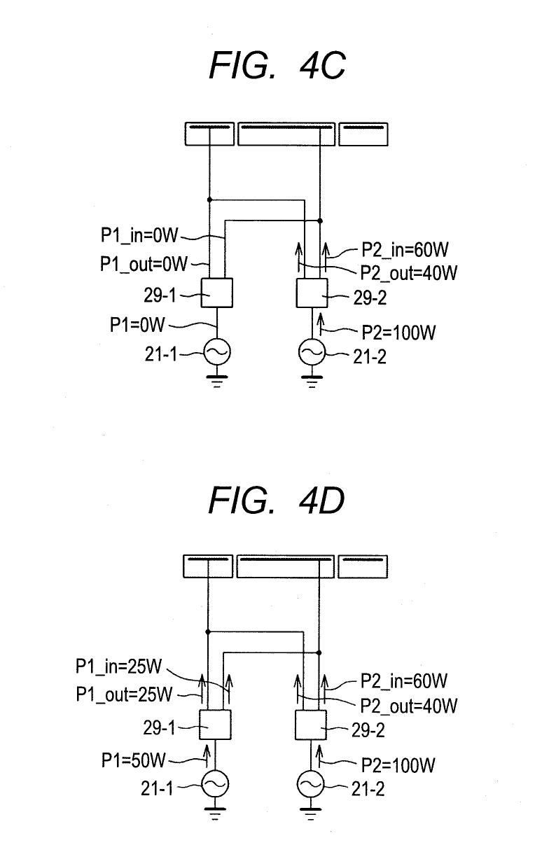

Next, an effect of independent control of the inner-to-outer power ratios of two bias powers of different frequencies will be described below. FIG. 4A to FIG. 4D are diagrams showing examples of applications of bias powers. FIG. 3A to FIG. 3D are diagrams showing the whole wafer surface uniformity in an IEDF. An IEDF observed near the edge of a wafer is presented on the right side of each of FIG. 3A to FIG. 3D, and an IEDF observed near the center of the wafer is presented on the left side thereof. The axis of abscissas indicates an energy level of ions incident on the wafer, and the axis of ordinates indicates an ion flux which exhibit the energy level and are incident on the wafer, that is, an energy distribution function of ions. FIG. 3A to FIG. 3D are associated with FIG. 4A to FIG. 4D respectively. Herein, a high-frequency power or a magnetic field for use in producing plasma remains unchanged.

FIG. 4A shows a case where P1 equals 50 W, P1_in equals 25 W, P2_out equals 25 W, and the inner-to-outer power ratio of the first bias power is 5:5. Incidentally, P2_in equals 0 W. In this case, an IEDF is, as shown in FIG. 3A, uniform inside the wafer surface.

FIG. 4B shows a case where P1 equals 0 W, P2 equals 100 W, P2_in equals 25 W, and P2_out equals 50 W, that is, the inner-to-outer power ratio of the second bias power is 5:5. In this case, an IEDF near the center of the wafer is, as shown in FIG. 3B, shifted to a lower energy side relative to an IEDF on the edge of the wafer. The IEDF inside the wafer surface is not uniform. This is attributable to frequency-dependence of impedance. As a frequency gets higher, a bias power to be applied to the vicinity of the center of the wafer becomes relatively smaller than a bias power to be applied to the vicinity of the edge of the wafer.

FIG. 4C and FIG. 3C show a case where, in order to make a whole wafer surface IEDF uniform, P1 is set to 0 W, P2 is set to 100 W, P2_in is set to 60 W, and P2_out is set to 40 W, that is, the inner-to-outer power ratio of the second bias power is set to 6:4. By changing the inner-to-outer power ratio of a bias power, as shown in FIG. 3C, an IEDF near the center of a wafer can be shifted to a higher energy side, and an IEDF on the edge of the wafer can be shifted to a lower energy side. As a result, the whole wafer surface IEDF can be made uniform.

FIG. 4D and FIG. 3D show a case where P1 equals 50 W, P1_in equals 25 W, P1_out equals 25 W, P2 equals 100 W, P2_in equals 60 W, and P2_out equals 40 W. When two wafer bias powers are applied simultaneously under the same condition as an inner-to-outer power ratio which makes an inner-surface IEDF, which is derived from a first wafer bias, and an IEDF, which is derived from a second wafer bias, uniform, a whole wafer surface IEDF determined with the two wafer bias powers becomes uniform.

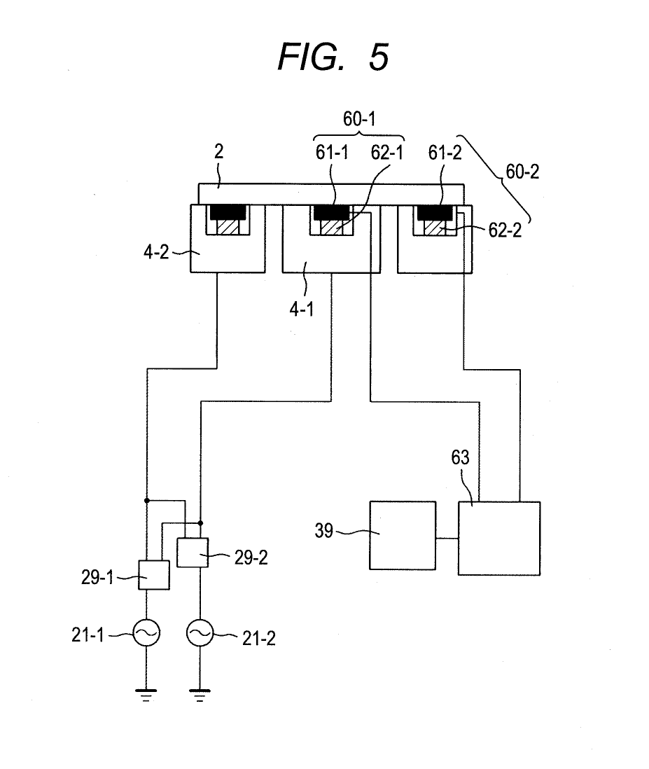

Next, a method of automatically adjusting the whole wafer surface uniformity in an IEDF using sensors mounted in the placement electrode (sample stage) will be described in conjunction with FIG. 5. Microscopic holes are formed in parts of the bias application plates (not shown in FIG. 5) of the inner electrode (sample stage) 4-1 and outer electrode (sample stage) 4-2 respectively, and an inner IEDF measurement sensor 60-1 and outer IEDF measurement sensors 60-2 are mounted.

The IEDF sensors 60-1 and 60-2 are each constructed by, for example, disposing a piezoelectric element 61-1 or 61-2 supported by an elastic body 62-1 or 62-2 so that the pressure-sensitive side thereof becomes an upper side. A distribution of the strength of an elastic wave propagated to the back of a wafer due to an impact of ions incident on the surface of the wafer 2 is detected using the piezoelectric element 61-1 or 61-2. Even when the wafer 2 is not disposed, the energy of ions incident on the elastic body 62-1 or 62-2 can be directly measured in order to obtain an IEDF.

An IEDF measurement unit 63 is used to monitor the output voltages of the piezoelectric elements 61-1 and 61-2 for a certain period of time. Among the monitored voltage values, the largest voltage value is associated with a maximum energy level of ions incident on the wafer, and the smallest voltage value is associated with a minimum energy level. Thus, the IEDF is evaluated. For converting the output voltages of the piezoelectric elements 61-1 and 61-2 into the ion energy levels, a database produced in advance in relation to each gas type employed and each mixing ratio is employed.

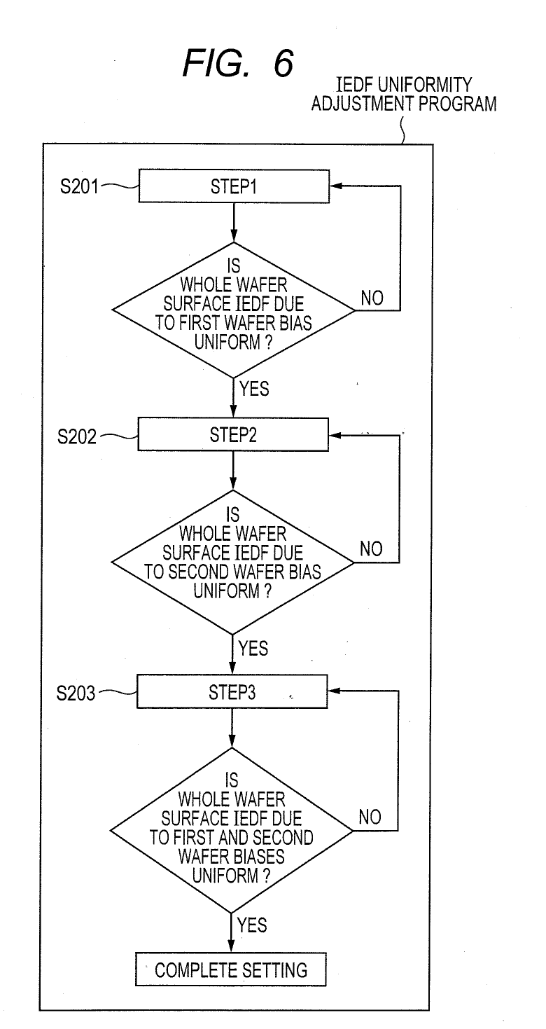

Measured data is transmitted to a control computer 39 that controls the whole of the plasma processing apparatus. A program of adjusting a whole wafer surface IEDF according to a procedure presented in FIG. 6 is installed in the control computer 39. First, at step 1 (S201), P1_in and P1_out are set to initial values and an IEDF is measured (if the initial values are not especially prepared, the inner-to-outer power ratio of the first bias power is set to 5:5).

If an IEDF is not uniform inside a wafer surface, the IEDF is corrected to become uniform (within ±5%). For example, when the IEDF near the center of the wafer is shifted to a relatively lower energy side, the percentage of the bias power P1_in is set to 50% or more. The IEDF is measured again, and the adjustment thereof is repeated until the inner-surface IEDF becomes uniform within a predetermined range. When the IEDF becomes uniform within the predetermined range, the second wafer biases P2_in and P2_out are set to the initial values at step 2 (S202), and an IEDF is measured. The adjustment of the IEDF is repeated according to the same technique as that employed at step 1 until the IEDF becomes uniform inside the wafer surface within the predetermined range (within ±5%).

Finally, at step 3 (S203), an IEDF is measured with the first and second bias powers P1 and P2 applied simultaneously, and checked to see if the IEDF is uniform inside the wafer surface within the predetermined range. If necessary, the inner-to-outer power ratio of the first or second bias power P1 or P2 is finely adjusted. When the IEDF becomes uniform inside the wafer surface (within ±5%), setting is completed.

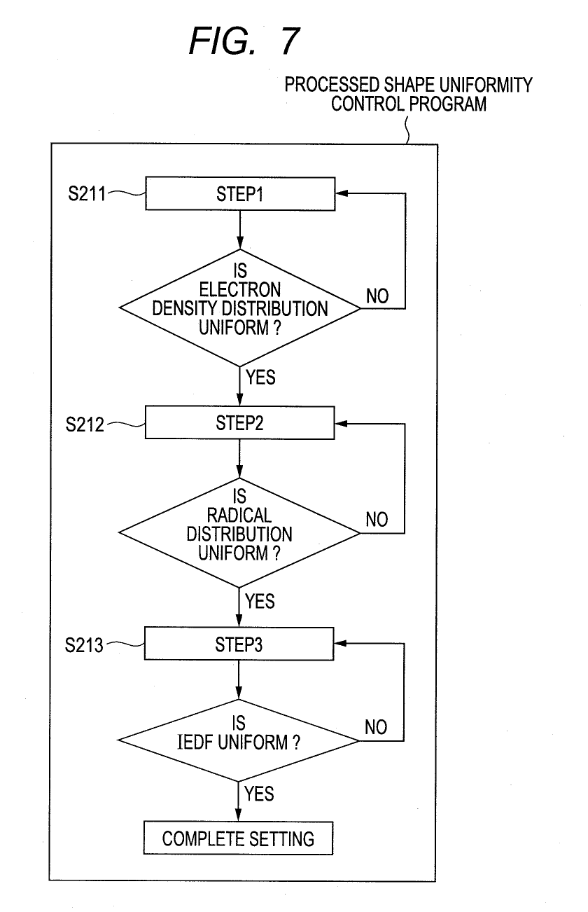

Next, a method of controlling the uniformity in a processed shape inside a wafer surface will be described in conjunction with FIG. 7. First, at step 1 (S211), a magnetic-field distribution is adjusted in order to adjust an electron density distribution (ion density distribution). The adjustment is achieved using the upper, middle, and lower coils 26-1, 26-2, and 26-3. For measurement of the electron density distribution, a Langmuir probe or a plasma absorption probe that is inserted from the flank of the chamber may be employed, or a method of measuring an ion saturation current density (ICF) on the surface of the placement electrode may be adopted.

When the electron density distribution becomes uniform within a predetermined range (within ±5%) by adjusting the magnetic-field distribution, a radical distribution is made uniform at step 2 (S212). This is achieved by independently controlling the compositions of gases, which are fed through the inner part of the shower plate and the outer part thereof, or the flow rates thereof. For the radical distribution, a technique of spectrophotometrically measuring plasma of a line integral domain, which is emitted in a direction parallel to a wafer, in plural directions immediately above the wafer, and obtaining a radial-direction density distribution of each of various radicals through Abel conversion is preferably adopted.

While the radical distribution is measured according to the above measurement technique, a gas flow rate is adjusted. When the adjustment is completed with the radical distribution made uniform within the predetermined range (within ±5%), adjustment of the next step 3 (S213) is begun. The contents of the adjustment of step 3 (S213) are presented in FIG. 6. Incidentally, since the radical distribution or IEDF depends on the electron density distribution alone, the electron density distribution is adjusted at the first step 1 (S211). However, the procedure presented in FIG. 7 may not be necessarily followed. For example, the procedure may be returned to step 1 (S211) in the middle of adjustment of step 3 (S213).

After the foregoing adjustments were completed, when a gate electrode was processed, an excellent result was obtained.

As mentioned above, according to the present embodiment, there are provided a plasma processing apparatus and a plasma processing method that improve the uniformity in a distribution function of incident ion energy inside a wafer surface, and realize uniform etching inside the wafer surface.

### Second Embodiment

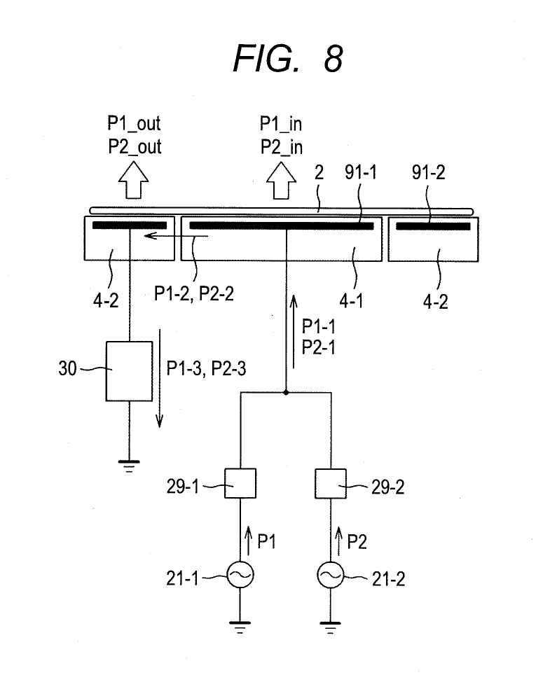

A second embodiment will be described in conjunction with FIG. 8. Items that have been described in relation to the first embodiment but will not be described in relation to the present embodiment can be applied as they are. FIG. 8 is a diagram for explaining applications of powers from bias power supplies connected to an entity-to-be-treated placement electrode. The other components are identical to those shown in FIG. 1. An iterative description is omitted.

In the present embodiment, a first wafer bias power and a second wafer bias power are applied to the inner electrode (sample stage) 4-1, and an impedance matcher 30 for adjusting impedance to a ground, that is, impedance occurring along a path led to a ground is connected to the outer electrode (sample stage) 4-2. The impedance matcher is designed to be able to independently control impedance occurring at the frequency of the first wafer bias and impedance occurring at the frequency of the second wafer bias.

The flows of powers are shown in FIG. 8. Both the first bias power P1 and second bias power P2 are applied to the inner electrode (sample stage) 4-1. Parts of the powers are transmitted to a plasma side through the vicinity of the center of a wafer, and become powers P1_in and P2_in respectively. A difference power P1-P1_in and a difference power P2-P2_in are transmitted to the outer electrode (sample stage) 4-2, and parts of the difference powers flow to the ground via the impedance matcher 30. Assuming that the parts of the difference powers are powers P1_3 and P2_3 respectively, powers P1_out and P2_out to be applied as biases to the edge of the wafer correspond to difference powers P1_2-P1_3 and P2_2-P2_3 respectively.

Namely, by adjusting the impedance matcher 30, the ratio of the power P1_in to the power P1_out and the ratio of the power P2_in to the power P2_out can be controlled. Unlike the case shown in FIG. 1, the powers P1_2 and P2_2 have to flow from the inner electrode to the outer electrode to some extent. The thickness of the bias application plates is increased or any other devisal is made.

After the foregoing adjustment was achieved, when a gate electrode was processed, an excellent result was obtained.

As mentioned above, according to the present embodiment, there are provided a plasma processing apparatus and a plasma processing method that improve the uniformity in a distribution function of incident ion energy inside a wafer surface, and realize uniform etching inside the wafer surface.

### Third Embodiment

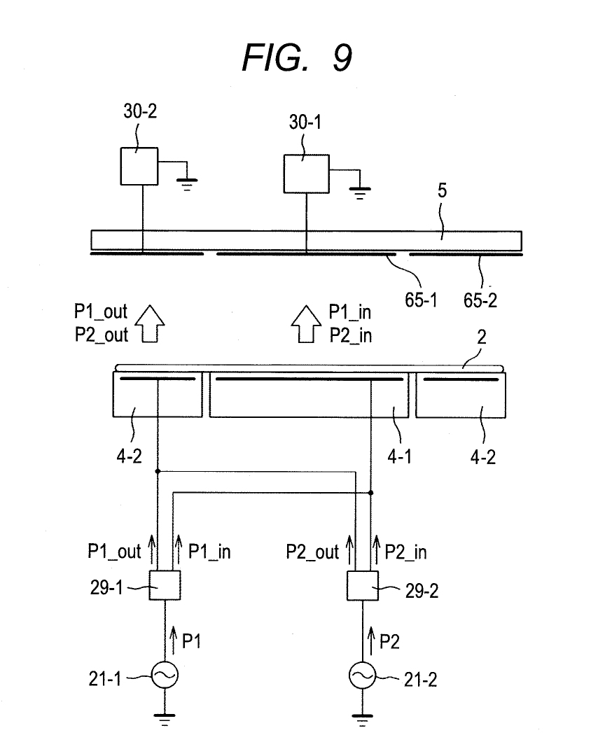

A third embodiment will be described in conjunction with FIG. 9. Items that have been described in relation to the first embodiment but will not be described in relation to the present embodiment can be applied as they are. FIG. 9 is a diagram for explaining applications of powers from bias power supplies connected to an entity-to-be-treated placement electrode of a plasma processing apparatus in accordance with the present embodiment. The other components are identical to those shown in FIG. 1, and an iterative description is omitted.

In the present embodiment, an opposite ground electrode is disposed immediately below the shower plate, and divided into two parts of an inner part 65-1 and an outer part 65-2. The opposite ground electrode is a conductive film that exhibits high transmittance relative to a high-frequency power to be used to produce plasma and that has a thickness which does not permit ready transmission of two wafer bias powers whose frequencies are lower than that of the high-frequency power to be used to produce plasma. The inner ground electrode 65-1 and outer ground electrode 65-2 are connected to an inner impedance matcher 30-1 and an outer impedance matcher 30-2 respectively. Gas introduction holes are formed in the inner ground electrode 65-1 and outer ground electrode 65-2, and the surfaces of the inner and outer ground electrodes are coated with quartz or the like. Thus, amounts of powers P1_in, P2_in, P1_out, and P2_out that flow through the opposite ground electrode can be adjusted. Eventually, controllability is improved compared with that in the case shown in FIG. 1.

After the foregoing adjustment was performed, when a gate electrode was processed, an excellent result was obtained.

As mentioned above, according to the present embodiment, there are provided a plasma processing apparatus and a plasma processing method that improve the uniformity in a distribution function of incident ion energy inside a wafer surface, and realize uniform etching inside the wafer surface. Since an opposite ground electrode is employed, the uniformity can be improved more greatly than that in the first embodiment.

### Fourth Embodiment

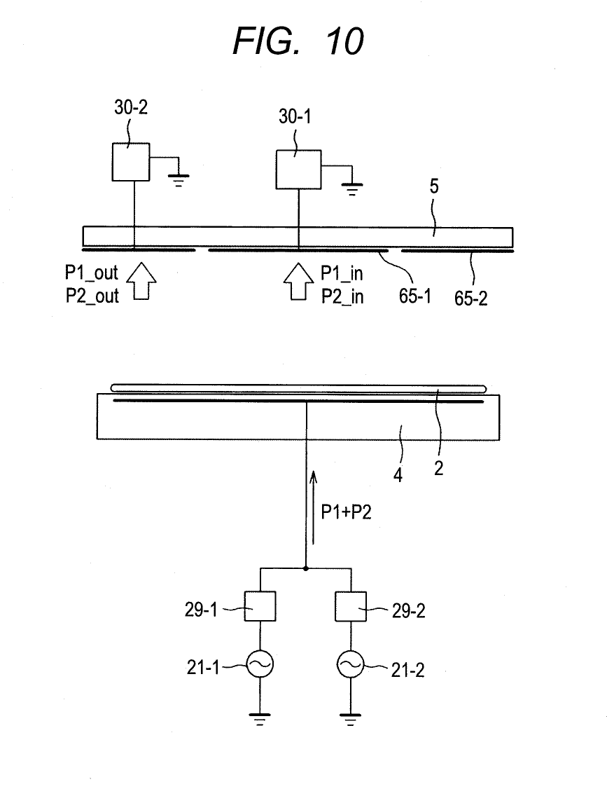

A fourth embodiment will be described in conjunction with FIG. 10. Items that have been described in relation to the first embodiment but will not be described in relation to the present embodiment can be applied as they are. FIG. 10 is a diagram for explaining application of powers from bias power supplies connected to an entity-to-be-treated placement electrode of a plasma processing apparatus in accordance with the present embodiment. The description and illustration of components identical to those of the third embodiment are omitted.

In the present embodiment, a wafer placement electrode is not divided into an inner part and an outer part, but two wafer bias powers of different frequencies are applied thereto. An opposite ground electrode is bifurcated into an inner part and an outer part. Impedances to grounds can be adjusted by an inner impedance matcher 30-1 and an outer impedance matcher 30-2. By adjusting impedance on the inside of the opposite ground electrode and impedance on the outside thereof, the ratio of a power P1_in to a power P1_out and the ratio of a power P2_in to a power P2_out can be controlled independently of each other. The inner and outer ground electrodes 65-1 and 65-2 are, similarly to those of the third embodiment, disposed immediately below the shower plate 5, have gas introduction holes formed therein, and has the surfaces thereof coated with quartz or the like. The opposite ground electrode may be disposed in the shower plate.

In the present embodiment, since an electrode in a sample stage immediately below a wafer is not divided into an inner electrode and an outer electrode. Compared with the other embodiments, an etching speed will not become unstable in a border area between the inner and outer electrodes. Uniformity in processing improves. In addition, since a structure is simple (the number of parts is small), non-uniformity in processing derived from a difference of one machine from another can be minimized. Further, effective voltage drops caused by an inner electrode and an outer electrode of an electrostatic chuck (not shown) can be, unlike the other embodiments, made equal to each other.

After the foregoing adjustment was performed, when a gate electrode was processed, an excellent result was obtained.

As mentioned above, according to the present embodiment, there are provided a plasma processing apparatus and a plasma processing method that improve the uniformity in a distribution function of incident ion energy inside a wafer surface, and realize uniform etching inside the wafer surface. In addition, since an opposite ground electrode is employed, the uniformity can be more greatly improved than that in the first embodiment. Further, since an electrode in a sample stage immediately below a wafer is not divided into an inner electrode and an outer electrode, the uniformity can be more greatly improved than that in the third embodiment.

### Fifth Embodiment

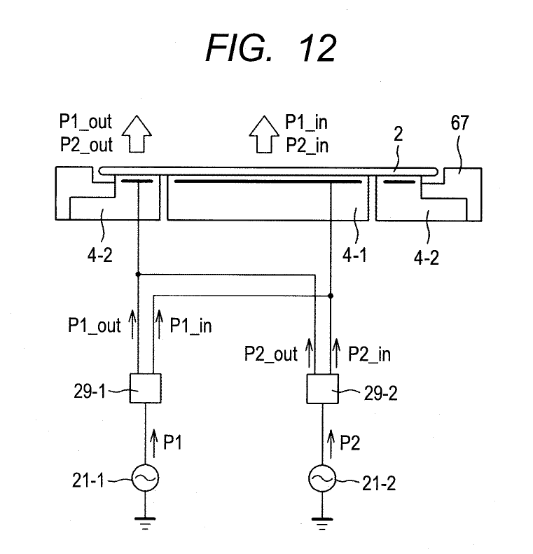

A fifth embodiment will be described in conjunction with FIG. 12. Incidentally, items that have been described in relation to any of the first to fourth embodiments but will not be described in relation to the present embodiment can be applied as they are. FIG. 12 is a diagram for explaining applications of powers from bias power supplies connected to an entity-to-be-treated placement electrode of a plasma processing apparatus in accordance with the present embodiment. Herein, the description and illustration of components identical to those of the third embodiment are omitted.

In the present embodiment, a focus ring 67 is disposed for covering the top and flank of the outer electrode 4-2. A wafer is placed on the tops of the inner electrode (sample stage) 4-1 and outer electrode (sample stage) 4-2, but is not in contact with the focus ring 67. The employment of the focus ring 67 makes it possible to protect an electrode-surface protecting film from being worn by ions incident on the top and flank of the outer electrode 4-2. Therefore, even when the energy of the ions incident on the outer electrode 4-2 is increased by controlling the ratio of a power P1_out to a power P2_out, the surface protecting film of the outer electrode 4-2 can be sustained. Further, since part of a bias power is fed to the focus ring 67, polymer accumulation on a mask at a wafer edge or uniformity in etching thereat can be controlled.

When the plasma processing apparatus having the foregoing constitution was used to process a gate electrode, an excellent result was obtained.

In the present embodiment, a frequency to be handled by the first high-frequency bias power supply 21-1 is 400 kHz, and a frequency to be handled by the second high-frequency bias power supply 21-2 is 4 MHz. Preferably, a difference between the frequencies of two bias powers is larger, because a controllable range of an IEDF is expanded. Besides, impedance on a wall surface of a chamber and impedance immediately above the wafer can be separated from each other. Further, one of the two frequencies may not be an integral multiple of the other so that harmonics of the frequencies can be utilized.

Further, in order to retain the independency of plasma production and IEDF control of each other, the frequency of a high-frequency bias is preferably lower than a frequency employed in the plasma production. For example, in the case of electron cyclotron resonance (ECR), when the frequency of the high-frequency bias is 100 MHz or more, it is hard to control an IEDF and a plasma density independently of each other. However, when the frequency of a low-frequency bias falls below 100 kHz, a charge-up phenomenon is likely to occur on an insulating layer on a silicon substrate. Therefore, the frequency of the low-frequency bias is 100 kHz or more and falls below 4 MHz, and the frequency of the high-frequency bias is 2 MHz or more and falls below 100 MHz. Preferably, frequencies having as large a difference between them as possible are used in combination.

Further, frequency bands to be mixed depend on a plasma generation mechanism. For example, when the plasma generation mechanism uses, as shown in FIG. 1, a magnetic field to control a distribution, the frequency of a high-frequency bias is set to 13.56 MHz in consideration of an effect of impedance caused by a magnetic field orthogonal to an electric field. For inductively coupled plasma (ICP) or capacitively coupled plasma (CCP), 27.60 MHz or the like may be used in coordination with a plasma source production frequency.

In the present embodiment, a description has been made by taking plasma etching for instance. The present invention may be applied to plasma chemical vapor deposition (CVD).

As mentioned above, according to the present embodiment, there are provided a plasma processing apparatus and a plasma processing method that improve the uniformity in a distribution function of incident ion energy inside a wafer surface, and realize uniform etching inside the wafer surface. In addition, since a focus ring is disposed for covering the top and flank of an outer electrode (sample stage), an electrode-surface protecting film can be protected from being worn due to ions incident on the top and flank of the outer electrode 4-2.

What is claimed is:

1. A plasma processing apparatus comprising a processing chamber, a processing gas feeding system that feeds processing gases to the processing chamber, a high-frequency power supply for use in producing plasma from the processing gases, a placement electrode which is disposed in the processing chamber and on which an entity to be processed is placed, and a first bias power supply and a second bias power supply that are used to accelerate ions which are present in the plasma and incident on the entity to be processed and that handle mutually different frequencies,
wherein the placement electrode has bias application portions thereof electrically divided into two electrodes of an inner electrode and an outer electrode at positions near the center of the entity to be processed and the edge thereof,
the plasma processing apparatus further comprising:
a first high-frequency bias power supply power distributor capable of bifurcating a bias power outputted from the first bias power supply, and feeding the resultant powers to the inner electrode and outer electrode while adjusting the power ratio; and
a second high-frequency bias power supply power distributor capable of bifurcating a bias power outputted from the second bias power supply, and feeding the resultant powers to the inner electrode and outer electrode while adjusting the power ratio.

2. A plasma processing apparatus comprising a processing chamber, a processing gas feeding system that feeds processing gases to the processing chamber, a high-frequency power supply for use in producing plasma from the processing gases, a placement electrode which is disposed in the processing chamber and on which an entity to be processed is placed, and a first bias power supply and a second bias power supply that are used to accelerate ions which are present in the plasma and incident on the entity to be processed and that handle mutually different frequencies, the plasma processing apparatus further comprising:
an inner ground electrode and an outer ground electrode disposed in an upper part of the processing chamber and opposed to the placement electrode;
a first impedance matcher connected to the inner ground electrode; and
a second impedance matcher connected to the outer ground electrode.

3. The plasma processing apparatus according to claim 1, wherein the placement electrode includes a focus ring disposed on the periphery of the outer electrode.

4. The plasma processing apparatus according to claim 1, wherein the processing gas feeding system includes:
a gas distributor that distributes the processing gases, which is mixed, into a first gas feed line and a second gas feed line;
an inner gas dispersion area linked to the first gas feed line and defined in the center area of the processing chamber; and
an outer gas dispersion area linked to the second gas feed line and defined in the perimetric area of the processing chamber.

5. The plasma processing apparatus according to claim 1, wherein the inner electrode and outer electrode of the placement electrode each include an ion energy distribution function measurement sensor.

6. The plasma processing apparatus according to claim 4, further comprising:
a magnetic-field production unit that enhances the efficiency in production of plasma; and
an ion energy distribution function measurement sensor mounted in each of the inner electrode and outer electrode of the placement electrode.

7. The plasma processing apparatus according to claim 2, wherein the placement electrode includes a focus ring disposed on the periphery of the outer electrode.

8. The plasma processing apparatus according to claim 2, wherein the processing gas feeding system includes:
a gas distributor that distributes the processing gases, which is mixed, into a first gas feed line and a second gas feed line;
an inner gas dispersion area linked to the first gas feed line and defined in the center area of the processing chamber; and
an outer gas dispersion area linked to the second gas feed line and defined in the perimetric area of the processing chamber.

9. The plasma processing apparatus according to claim 2, wherein the placement electrode includes an ion energy distribution function measurement sensor.

10. The plasma processing apparatus according to claim 8, further comprising:
a magnetic-field production unit that enhances the efficiency in production of plasma; and
an ion energy distribution function measurement sensor mounted in the placement electrode.

11. The plasma processing apparatus according to claim 2, wherein the placement electrode includes two electrodes of an inner electrode and an outer electrode into which a bias application portion thereof is electrically divided at positions near the center of the entity to be processed and the edge thereof.

12. A plasma processing apparatus comprising a processing chamber, a processing gas feeding system that feeds a processing gas to the processing chamber, a high-frequency power supply for use in producing plasma from the processing gas, a placement electrode which is disposed in the processing chamber and on which an entity to be processed is placed, and a first bias power supply and a second bias power supply that are used to accelerate ions which are present in the plasma and incident on the entity to be processed and that handle mutually different frequencies,
wherein the placement electrode has bias application portions thereof electrically divided into two electrodes of an inner electrode and an outer electrode at positions near the center of the entity to be processed and the edge thereof, and bias powers outputted from the first bias power supply and second bias power supply are applied to the inner electrode,
the plasma processing apparatus further comprising:
an impedance matcher that is connected to the outer electrode in order to adjust impedance to a ground.

13. A plasma processing method employing the plasma processing apparatus according to claim 1, comprising:
generating the plasma; and
bringing an ion energy distribution function to a distribution, which is uniform inside the surface of the entity to be processed, by adjusting bias powers outputted from the first bias power supply and second bias power supply.

14. A plasma processing method employing the plasma processing apparatus according to claim 5, comprising:
feeding a bias power outputted from the first bias power supply to the inner electrode and outer electrode, and bringing an ion energy distribution function to a distribution, which is uniform inside the surface of the entity to be processed, using the ion energy distribution function measurement sensor mounted in each of the inner electrode and outer electrode;
feeding a bias power outputted from the second bias power supply to the inner electrode and outer electrode, and bringing an ion energy distribution function to a distribution, which is uniform inside the surface of the entity to be processed, using the ion energy distribution function measurement sensor mounted in each of the inner electrode and outer electrode; and
feeding the bias powers outputted from the first bias power supply and second bias power supply to the inner electrode and outer electrode, and bringing an ion energy distribution function to a distribution, which is uniform inside the surface of the entity to be processed, using the ion energy distribution function measurement sensor mounted in each of the inner electrode and outer electrode.

15. A plasma processing method employing the plasma processing apparatus according to claim 6, comprising:
making an electron density distribution uniform by adjusting a magnetic-field distribution in the processing chamber using the magnetic-field generation unit;
making a radical distribution uniform by adjusting flow rates of a reactive gas to the inner gas dispersion area and outer gas dispersion area; and
bringing an ion energy distribution function to a distribution, which is uniform inside the surface of the entity to be processed, by adjusting bias powers outputted from the first bias power supply and second bias power supply.

16. A plasma processing method employing the plasma processing apparatus according to claim 2, comprising:
generating the plasma; and
bringing an ion energy distribution function to a distribution, which is uniform inside the surface of the entity to be processed, by adjusting the first impedance matcher and second impedance matcher.

17. A plasma processing method employing the plasma processing apparatus according to claim 10, comprising:
making an electron density distribution uniform by adjusting a magnetic-field distribution in the processing chamber using the magnetic-field generation unit;
making a radical distribution uniform by adjusting flow rates of the reactive gas to the inner gas dispersion area and outer gas dispersion area; and
bringing an ion energy distribution function to a distribution, which is uniform inside the surface of the entity to be processed, by adjusting the first impedance matcher and second impedance matcher.
